(19) United States
(12) Patent Application Publication
(10) Pub. No.: US 2007/0069255 A1
(43) Pub. Date: Mar. 29, 2007

(54) MOS TRANSISTORS HAVING OPTIMIZED CHANNEL PLANE ORIENTATION, SEMICONDUCTOR DEVICES INCLUDING THE SAME, AND METHODS OF FABRICATING THE SAME

(75) Inventor: Il-Gweon KIM, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-Do, (KR)

(21) Appl. No.: 11/466,431

(22) Filed: Aug. 22, 2006

(30) Foreign Application Priority Data
Sep. 12, 2005 (KR) 2005-0084862

(51) Int. Cl. H01L 29/76

(52) U.S. Cl. 257/288

(57) ABSTRACT

MOS transistors having an optimized channel plane orientation are provided. The MOS transistors include a semiconductor substrate having a main surface of a (100) plane. An isolation layer is provided in a predetermined region of the semiconductor substrate to define an active region. A source region and a drain region are disposed in the active region. The source and drain regions are disposed on a straight line parallel to a <100> orientation. An insulated gate electrode is disposed over a channel region between the source and drain regions. Methods of fabricating the MOS transistors are also provided.

### CROSS-REFERENCE TO RELATED APPLICATION

This application claims the benefit of Korean Patent Application No. 10-2005-0084862, filed Sep. 12, 2005, the disclosure of which is hereby incorporated by reference herein in its entirety.

### BACKGROUND

1. Field of the Invention

The present invention relates to semiconductor devices and methods of fabricating the same and, more particularly, to MOS transistors having an optimized channel plane orientation, semiconductor devices including the same and methods of fabricating the same.

2. Description of the Related Art

Most semiconductor devices employ MOS (Metal-Oxide-Semiconductor) transistors as active devices, such as switching devices. CMOS (Complementary MOS) integrated circuits (IC) including NMOS (N-channel MOS) transistors and PMOS (P-channel MOS) transistors have been widely used to reduce power consumption of semiconductor devices. However, in order to enhance the electrical characteristics of CMOS ICs, NMOS and PMOS transistors should have improved current drivability.

NMOS transistors are widely used as cell transistors of semiconductor memory devices such as DRAM (dynamic random access memory) devices. Accordingly, NMOS transistors should have high current drivability to realize high-performance DRAM cells. The current drivability of NMOS transistors may be directly affected by carrier mobility in the channel regions of the devices. In other words, the electrical characteristics (e.g., switching speed) of the NMOS transistors are closely related with the carrier mobility in the channel regions. Consequently, to improve high-performance DRAM cells, the electron mobility in the channel regions should be increased.

Carrier mobility depends on the plane orientation of the channel region. For example, when an NMOS transistor is formed on a semiconductor substrate having a (100) plane, it is well known in the art that the NMOS transistor will have a maximum electron mobility of about 350 cm²/V·S.

In recent years, however, cell transistors having a recessed channel region are widely used in order to improve the cell leakage current characteristic and integration density of the DRAM devices. The recessed channel region may be defined by forming an isolation layer in a predetermined region of a semiconductor substrate to define an active region and forming a channel trench region across the active region. In this case, the recessed channel region may be formed along a bottom surface and sidewalls of the channel trench region. Accordingly, the current drivability of a MOS transistor fabricated in and on the wafer's exterior surface having the recessed channel region may be directly affected by the plane orientations of the bottom surface and sidewalls of the channel trench region, i.e. the planar orientation of the channel region relative to the planar orientation of the internal lattice structure of the wafer.

FIGS. 1A through 1C schematically illustrate three principal plane orientations of silicon having a diamond-like cubic lattice structure.

Referring to FIGS. 1A through 1C, an x-axis, a y-axis, and a z-axis are provided to be orthogonal to one another, and one cubic structure aligned with the x-, y-, and z-axes may be defined. The cubic structure has six faces and eight vertices A, B, C, D, E, F, G, and H. In a coordinate system with the x-, y-, and z-axes, the vertices A, B, C, and D are located at first coordinates (1, 0, 0), second coordinates (1, 1, 0), third coordinates (0, 1, 0), and fourth coordinates (0, 0, 0), respectively, and the vertices E, F, G, and H are located at fifth coordinates (1, 0, 1), sixth coordinates (1, 1, 1), seventh coordinates (0, 1, 1), and eighth coordinates (0, 0, 1), respectively. Thus, a face (ABFE of FIG. 1A) having the first, second, sixth, and fifth vertices A, B, F, and E has a (100) plane orientation, and a face (ACGE of FIG. 1B) having the first, third, seventh, and fifth vertices A, C, G, and E has a (110) plane orientation. Also, a face (ACH of FIG. 1C) having the first, third, and eighth vertices A, C, and H has a (111) plane orientation.

Three plane orientations (100), (110), and (111), which are described above, correspond to principal plane orientations of material having a diamond-like cubic lattice structure. That is, it can be considered that the faces ABCD, BCGF, DCGH, EFGH, and ADHE in FIGS. 1A through 1C all have the same plane orientation as the face ABFE. Thus, all the faces ABCD, BCGF, DCGH, EFGH, ADHE, and ABFE belong to one family group, and the plane orientation thereof may be expressed by “{100}” (see FIG. 1A). Also, it may be considered that a face DBFH has the same plane orientation as the face ACGE. Thus, the faces DBFH and ACGE also belong to one family group and the plane orientation thereof may be expressed by “{110}” (see FIG. 1B).

Conventional semiconductor wafers have generally been fabricated to include a main surface having a (100) plane orientation and a flat zone plane having a (110) plane orientation. The flat zone plane functions as a reference region for aligning the semiconductor wafer during several process steps for fabricating semiconductor devices on the semiconductor wafer. For example, during a photolithography process for forming desired patterns on the semiconductor wafer, the flat zone plane serves as a reference region for aligning the semiconductor wafer with a photo mask used in the photolithography process. Therefore, when a cell transistor having a recessed channel region is formed using the conventional semiconductor wafer, sidewalls of a channel trench region defining the recessed channel region conventionally are formed parallel or perpendicular to the flat zone plane. This is because an active region where the recessed channel region is formed is generally aligned parallel or perpendicular to the flat zone plane. As a result, the bottom surface of the channel trench region has the same (100) plane orientation as the main surface of the conventional semiconductor wafer, whereas sidewalls of the channel trench region have the same (110) plane orientation as the flat zone plane of the conventional semiconductor wafer.

Further, carriers (e.g., electrons) move along a direction parallel to a <110> orientation in a channel region under the channel trench bottom surface having a (100) plane. Also, carriers (e.g., electrons) moving at the channel trench sidewalls having a (110) plane orientation are drifted along a <100> orientation. Accordingly, when the cell transistor having the recessed channel region is an NMOS transistor, the current drivability of the cell transistor can be significantly degraded. This is because the electrons are not moving along a direction oriented along the plane of the underlying material (internal cubic lattice) structure. In other words, when the electrons move along the <100> orientation in the (100) plane, the electron mobility is maximized. Therefore, in order to improve the current drivability of NMOS transistors having the recessed channel region, all the bottom surface and sidewalls of the channel trench region that defines the recessed channel region should be formed to have (100) planes, and the NMOS transistors should be designed such that the carriers (i.e., the electrons) move along the <100> orientation in the bottom surface and sidewalls of the channel trench region.

A method of forming a trench isolation region having vertical sidewalls of (100) planes is disclosed in U.S. Pat. No. 6,537,895 B1 to Miller, et al., entitled “Method of Forming Shallow Trench Isolation in a Silicon Wafer”. According to Miller, et al., a silicon wafer is rotated or moved such that a flat zone plane of the silicon wafer is parallel to a (100) plane, and a trench isolation region having sidewalls parallel or perpendicular to the flat zone plane is formed in the silicon wafer.

Furthermore, a MOS transistor having a vertical channel of a (100) plane and a method of fabricating the same are disclosed in Japanese Laid-open Patent No. 11-274485 to Matsuura, et al., entitled “Insulated CGate Type Semiconductor Device and its Manufacturing Method”. According to Matsuura, et al., a vertical MOS transistor is formed using a wafer having a main surface with a (100) plane orientation and a flat zone plane with the (100) plane orientation. Accordingly, a channel region of the vertical MOS transistor is formed to have a (100) plane, thereby increasing the on-current.

### SUMMARY

In one embodiment, the present invention is directed to MOS transistors having a channel region suitable for improving carrier mobility. The MOS transistors include a semiconductor substrate having a main surface of a (100) plane. An isolation layer is provided in a predetermined region of the semiconductor substrate to define an active region. A source region and a drain region are provided in the active region. The source and drain regions are disposed on a straight line parallel to a <100> orientation. A gate electrode covers a channel region between the source and drain regions.

### BRIEF DESCRIPTION OF THE DRAWINGS

The features and advantages of the invention will be apparent from the detailed description of exemplary embodiments of the invention, as illustrated in the accompanying drawings. The drawings are not necessarily to scale, emphasis instead being placed upon illustrating the principles of the invention.

FIGS. 1A through 1C schematically illustrate principal plane orientations of silicon having a diamond-like cubic lattice structure.

FIG. 2A is an isometric view of a semiconductor wafer having optimized channel regions of MOS transistors according to an embodiment of the present invention.

FIG. 2B is an isometric view of a semiconductor wafer having optimized channel regions of MOS transistors according to another embodiment of the present invention.

FIG. 3 is a plan view of memory cells employing MOS transistors according to an embodiment of the present invention.

FIGS. 4A, 5A, 6A, 7A, and 8A are cross-sectional views taken along line I-I′ of FIG. 3, which illustrate methods of fabricating memory cells having MOS transistors according to an embodiment of the present invention.

FIGS. 4B, 5B, 6B, 7B, and 8B are cross-sectional views taken along line II-II′ of FIG. 3, which illustrate methods of fabricating memory cells having MOS transistors according to an embodiment of the present invention.

FIG. 9 is an isometric view of a semiconductor wafer used in fabrication of MOS transistors according to another embodiment of the present invention.

FIG. 10 is a cross-sectional view taken along line III-III′ of FIG. 9.

FIG. 11 is a graph showing current-voltage (I-V) curves of MOS transistors fabricated according to the conventional art and the present invention.

FIG. 12 is a graph illustrating on-current versus threshold voltage characteristics of MOS transistors fabricated according to the conventional art and the present invention.

FIG. 13 is a graph showing the number of failure cells according to word line voltage in DRAM devices employing conventional MOS transistors as cell transistors.

FIG. 14 is a graph showing the number of failure cells according to word line voltage in DRAM devices employing MOS transistors according to an embodiment of the present invention as cell transistors.

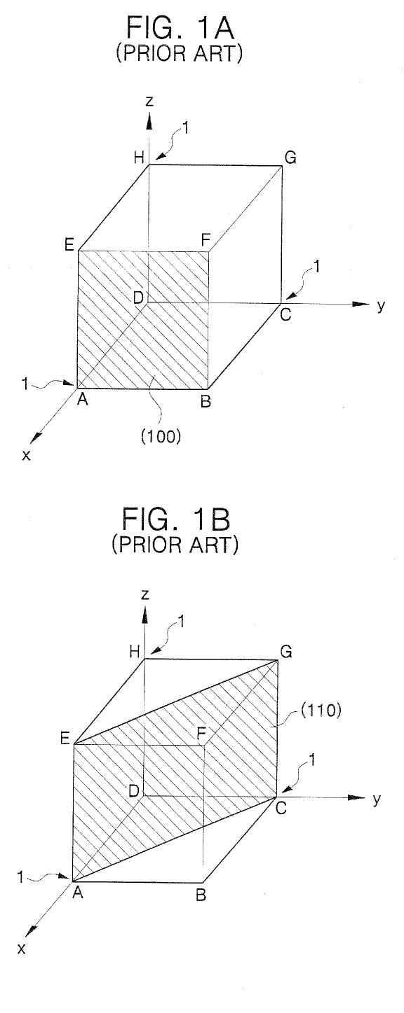

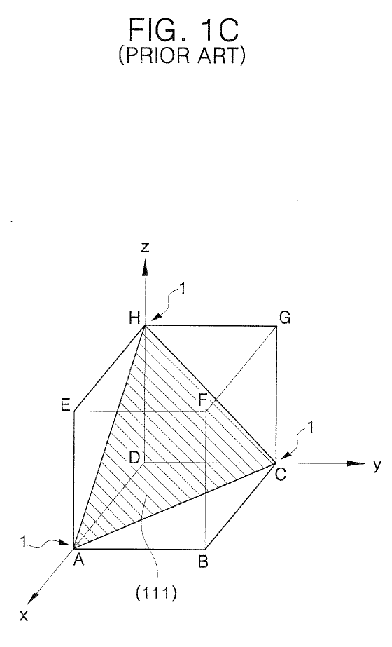

### DETAILED DESCRIPTION

The present invention will now be described more fully hereinafter with reference to the accompanying drawings, in which exemplary embodiments of the invention are shown. This invention may, however, be embodied in different forms and should not be construed as limited to the embodiments set forth herein. Rather, these embodiments are provided so that this disclosure is thorough and complete and fully conveys the scope of the invention to those skilled in the art. In the drawings, the thicknesses of layers and regions are exaggerated for clarity. The same reference numerals are used to denote the like elements.

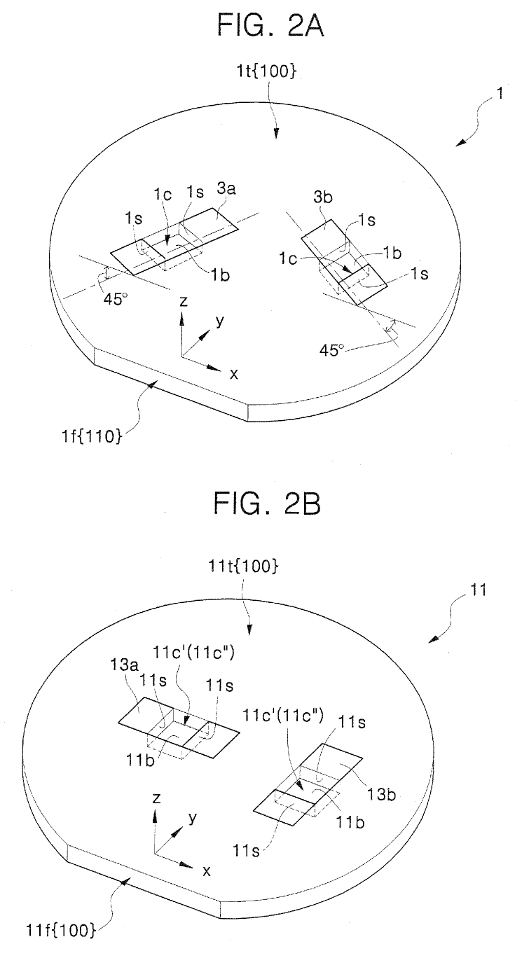

FIG. 2A is an isometric view of a semiconductor wafer having optimized channel regions of MOS transistors according to an embodiment of the present invention, and FIG. 2B is a perspective view of a semiconductor wafer having optimized channel regions of MOS transistors according to another embodiment of the present invention.

Referring to FIG. 2A, a semiconductor wafer 1 having a main surface 1t of a (100) plane is provided. The semiconductor wafer 1 may have a flat zone plane 1f perpendicular to the main surface 1t. In the present embodiment, the flat zone plane 1f may have a (110) plane orientation and the semiconductor wafer 1 may be a single crystalline silicon wafer. The main surface 1t is parallel to an x-y plane defined by an x-axis and a y-axis, and the flat zone plane 1f is parallel to an x-z plane defined by the x-axis and a z-axis. The x-, y-, and z-axes are coordinate axes, which are orthogonal to one another.

A first active region 3a and a second active region 3b may be provided at the main surface 1t of the semiconductor wafer 1, and each of the first and second active regions 3a and 3b may have a width and a length greater than the width. In this case, the direction that the length dimension of the first active region 3a is oriented may be perpendicular to the direction that the length dimension of the second active region 3b is oriented. Also, the first active region 3a may be disposed parallel to a (dash-dot) straight line that intersects the flat zone plane 1f at an angle of about 45°, and the second active region 3b may be disposed parallel to another (dash-dot) straight line that intersects the flat zone plane if at an angle of about 45°. As a result, the direction of the length dimensions (also referred to herein as “length directions”) of the first and second active regions 3a and 3b may be parallel to a <100> orientation, and the z-axis may also be parallel to the <100> orientation.

A channel trench region 1c is provided in the first active region 3a to define a recessed channel region. The channel trench region 1c is disposed across the first active region 3a. In this case, the channel trench region 1c may include a bottom surface 1b parallel to the main surface 1t as well as a pair of first and second sidewalls 1s facing each other. Since the bottom surface 1b is parallel to the main surface 1t, the bottom surface 1b also has a (100) plane orientation. The first and second sidewalls 1s are adjacent to the first active region 3a. Also, the first and second sidewalls 1s may be parallel to a plane that intersects the flat zone plane 1f at an angle of about 45°. Accordingly, the first and second sidewalls 1s may also have the {100} plane orientation. As a result, all of the surfaces 1b and 1s of the channel trench region 1c may be oriented in {100} planes. It will be appreciated that the terms “(100) plane orientation” and “{100} planes” are used interchangeably herein to refer to an orthogonal cubic planar orientation system relative to a reference or baseline conventional (xyz) Cartesian coordinate system, as described above. Also, carriers (e.g., electrons), which move from one end of the first active region 3a toward the other end thereof along all the surfaces 1b and 1s of the channel trench region 1c, are drifted along the <100> orientation. Thus, a MOS transistor employing the channel trench region 1c in the first active region 3a as a recessed channel region may exhibit improved current drivability.

Further, a channel trench region 1c may be provided across the second active region 3b. The channel trench region 1c in the second active region 3b may also include a bottom surface 1b parallel to the main surface 1t as well as a pair of first and second sidewalls 1s facing each other. In this case, the bottom surface 1b and the sidewalls 1s of the channel trench region 1c in the second active region 3b may also be oriented in {100} planes, and carriers (e.g., electrons), which move from one end of the second active region 3b toward the other end thereof along the bottom surface 1b and the sidewalls 1s of the channel trench region 1c in the second active region 3b, may also be drifted along the <100> orientation. Thus, a MOS transistor employing the channel trench region 1c in the second active region 3b as a recessed channel region may also exhibit improved current drivability.

Referring to FIG. 2B, a semiconductor wafer 11 having a main surface 11t of a {100} plane is provided. The semiconductor wafer 11 may have a flat zone plane 11f perpendicular to the main surface 11t. In the present embodiment, the flat zone plane 11f has a {100} plane orientation and the semiconductor wafer 11 may be a single crystalline silicon wafer. The main surface 11t is parallel to an x-y plane defined by an x-axis and a y-axis, and the flat zone plane 11f is parallel to an x-z plane defined by the x-axis and a z-axis. The x-, y-, and z-axes are coordinate axes orthogonal to one another.

A first active region 13a and a second active region 13b may be provided at the main surface 11t of the semiconductor wafer 11, and each of the first and second (elongate) active regions 13a and 13b may have a width and a length greater than the width. The first (elongate) active region 13a may be disposed parallel to the flat zone plane 11f, and the second (elongate) active region 13b may be disposed perpendicular to the flat zone plane 11f. As a result, length directions of the first and second active regions 13a and 13b may be parallel to a <100> orientation, and the z-axis may also be parallel to the <100> orientation.

A channel trench region 11c′ or 11c″ is provided in the first active region 13a to define a recessed channel region. The channel trench region 11c′ or 11c″ is provided across the first (elongate) active region 13a. In this case, the channel trench region 11c′ or 11c″ may include a bottom surface 11b parallel to the main surface 11t as well as a pair of first and second sidewalls 11s facing each other. Since the bottom surface 11b is parallel to the main surface 11t, the bottom surface 11b also has a {100} plane orientation. The first and second sidewalls 11s are adjacent to the first active region 13a. Also, the first and second sidewalls 11s may be parallel to a plane perpendicular to the flat zone plane 11f. Accordingly, the first and second sidewalls 11s may also have the {100} plane orientation. As a result, all the surfaces 11b and 11s of the channel trench region 11c′ or 11c″ may be oriented in {100} planes. Also, carriers (e.g., electrons), which move from one end of the first active region 13a toward the other end thereof along all the surfaces 11b and 11s of the channel trench region 11c′ or 11c″, may be drifted along the <100> orientation. Thus, a MOS transistor employing the channel trench region 11c′ or 11c″ disposed in the first active region 13a as a recessed channel region may exhibit improved current drivability.

Further, a channel trench region 11c′ or 11c″ may be provided across the second active region 13b. The channel trench region 11c′ or 11c″ in the second active region 13b may also include a bottom surface 11b parallel to the main surface 11t as well as a pair of first and second sidewalls 11s facing each other. In this case, the bottom surface 11b and the sidewalls 11s of the channel trench region 11c′ or 11c″ in the second active region 13b may also be oriented in the {100} planes, and carriers (e.g., electrons), which move from one end of the second active region 13b toward the other end thereof along the bottom surface 11b and the sidewalls 11s of the channel trench region 11c′ or 11c″ in the second active region 13b, may also be drifted along the <100> orientation. Thus, a MOS transistor employing the channel trench region 11c′ or 11c″ in the second active region 13b as a recessed channel region may also exhibit improved current drivability.

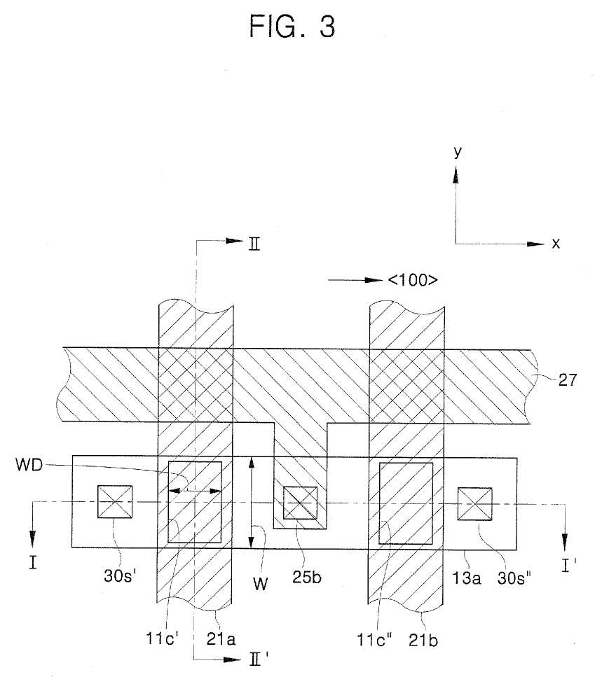

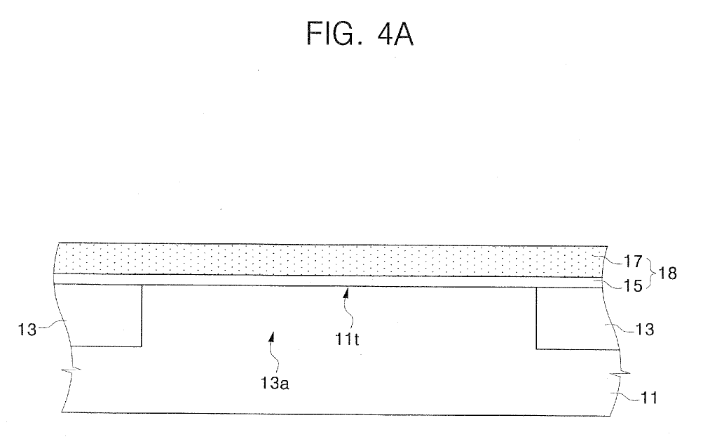

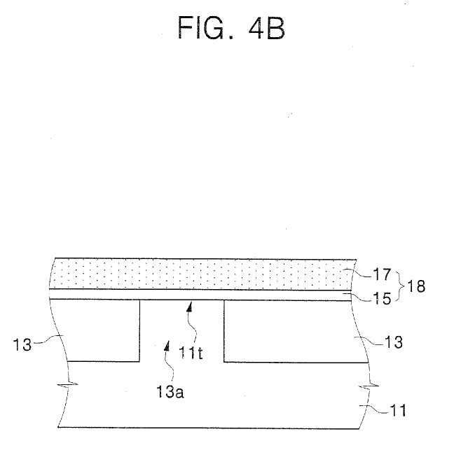

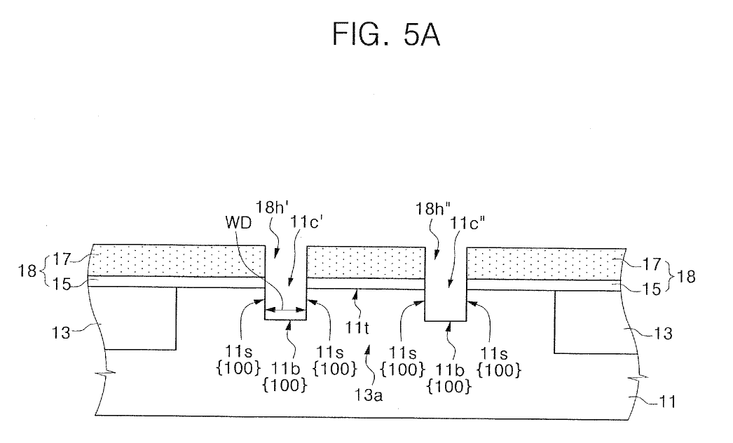

FIG. 3 is a plan view of a pair of DRAM cells employing MOS transistors according to an embodiment of the present invention. FIGS. 4A, 5A, 6A, 7A, and 8A are cross-sectional views taken along line I-I′ of FIG. 3, which illustrate methods of fabricating DRAM cells according to an embodiment of the present invention, and FIGS. 4B, 5B, 6B, 7B, and 8B are cross-sectional views taken along line II-II′ of FIG. 3, which illustrate methods of fabricating DRAM cells according to an embodiment of the present invention.

Referring to FIGS. 3, 4A, and 4B, a semiconductor substrate 11 such as a single crystalline silicon wafer is provided. For the purpose of ease and convenience in explanation, it is assumed that the semiconductor substrate 11 is identical to the semiconductor wafer shown in FIG. 2B. In other words, it is assumed that the semiconductor substrate 11 is a wafer having a main surface 11t with a {100} plane orientation and a flat zone plane (11f of FIG. 2B) with the {100} plane orientation. Also, it is assumed that the main surface 11t is parallel to an x-y plane defined by an x-axis and a y-axis that are orthogonal to each other.

An isolation layer 13 is formed in a predetermined region of the semiconductor substrate 11 to define an active region 13a. The active region 13a may have a width and a length greater than the width. In this case, the active region 13a may be defined to be parallel to the flat zone plane 11f. That is, the active region 13a may be parallel to the x-axis as shown in FIG. 3. As a result, a length direction of the active region 13a may be parallel to a <100> orientation. A hard mask layer 18 is then formed on the semiconductor substrate 11 having the isolation layer 13. The hard mask layer 18 may be formed by sequentially stacking a buffer oxide layer 15 and a pad nitride layer 17.

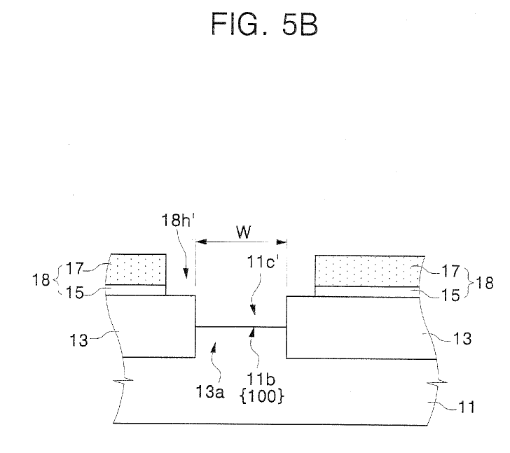

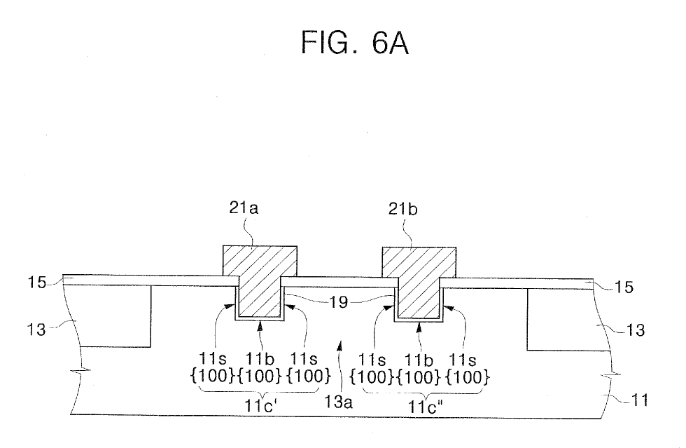

Referring to FIGS. 3, 5A, and 5B, the hard mask layer 18 is patterned to form first and second parallel openings 18′ and 18h″ that cross over the active region 13a. The active region 13a is selectively etched using the patterned hard mask layer 18 as an etch mask, thereby forming a first channel trench region 11c′ and a second channel trench region 11c″ that cross the active region 13a. As a result, each of the first and second channel trench regions 11c′ and 11c″ may include a bottom surface 11b lower than the main surface 11t (see FIG. 5A) as well as four sidewalls. The four sidewalls may include a pair of first and second sidewalls 11s contacting the active region 13a and facing each other (see FIG. 5A) as well as another pair of sidewalls (not shown) contacting the isolation layer 13 and facing each other. Accordingly, since the first and second sidewalls 11s contacting the active region 13a are formed perpendicular to the flat zone plane 11f, the first and second sidewalls 11s may have the (100) plane orientation. Also, the bottom surface 11b is formed parallel to the main surface 11t. Thus, the bottom surface 11b may also have the (100) plane orientation.

The first and second channel trench regions 11c′ and 11c″ define a first recessed channel region and a second recessed channel region, respectively. The width of the recessed channel regions may be equal to a width W of the active region 13a (see FIGS. 3 and 5B) and the channel length of the recessed channel regions may be greater than a width WD of the bottom surface 11b (see FIGS. 3 and 5A).

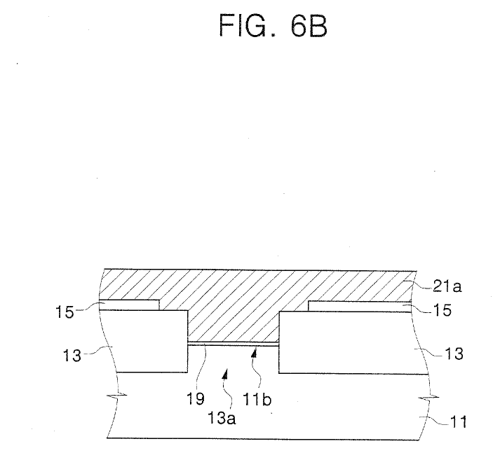

Referring to FIGS. 3, 4A, 6A, and 6B, the patterned pad nitride layer 17 (see FIG. 4A) is selectively removed, and a gate insulating layer 19 (see FIGS. 6A and 6B) is formed on the bottom surface 11b and the inner sidewalls 11s of the channel trench regions 11c′ and 11c″. Alternatively, the gate insulating layer 19 may be formed after removal of the patterned hard mask layer 18. In this case, the gate insulating layer 19 may be formed on the bottom surface 11b and the inner sidewalls 11s of the channel trench regions 11c′ and 11c″, as well as on the surface of the active region 13a. The gate insulating layer 19 may be formed of a thermal oxide layer.

Subsequently, a gate conductive layer filling the channel trench regions 11c′ and 11c″ is formed on the semiconductor substrate 11 having the gate insulating layer 19. The gate conductive layer may be formed of a polysilicon layer or a metal polycide layer. The gate conductive layer is patterned to form a first gate electrode 21a and a second gate electrode 21b crossing over the active region 13a. The first and second gate electrodes 21a and 21b are formed to cover the first and second channel trench regions 11c′ and 11c″, respectively. The first and second gate electrodes 21a and 21b may act as first and second word lines, respectively.

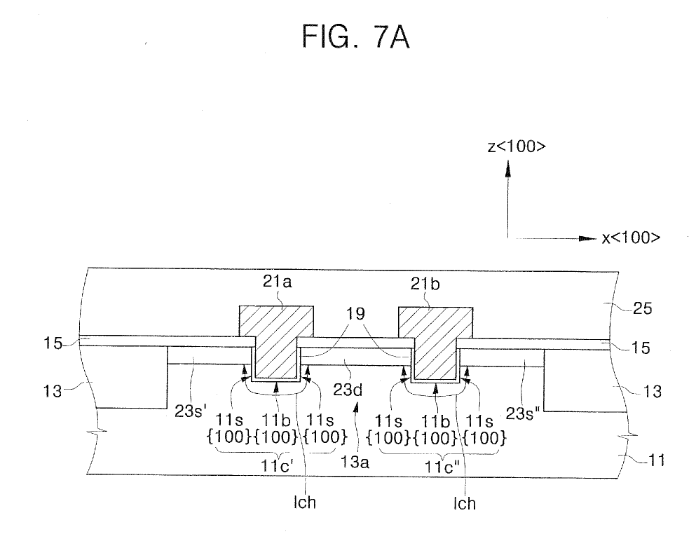

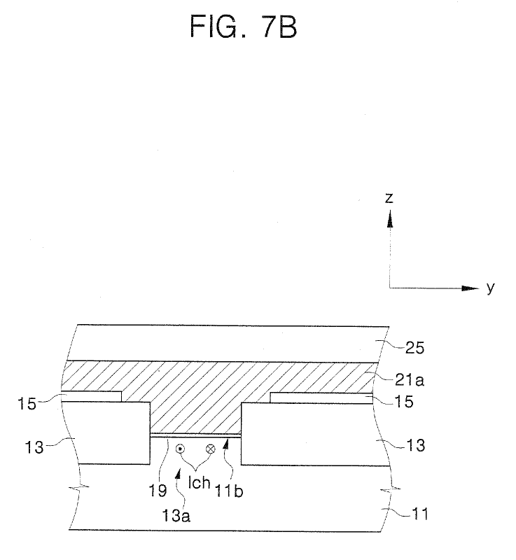

Referring to FIGS. 3, 7A, and 7B, impurity ions are implanted into the active region 13a using the first and second gate electrodes 21a and 21b and the isolation layer 13 as ion implantation masks, thereby forming a first source region 23s′, a second source region 23s″, and a common drain region 23d. The common drain region 23d is formed in the active region 13a between the first and second gate electrodes 21a and 21b. The first source region 23s′ is formed in the active region 13a which is adjacent to the first gate electrode 21a and located opposite the common drain region 23d, and the second source region 23s″ is formed in the active region 13a which is adjacent to the second gate electrode 21b and located opposite the common drain region 23d. The first gate electrode 21a, the first source region 23s′, and the common source region 23d constitute a first cell transistor, and the second gate electrode 21b, the second source region 23s″, and the common drain region 23d constitute a second cell transistor.

The first and second source regions 23s′ and 23s″ and the common drain region 23d may be formed to have a junction depth which is less than the depth of the channel trench regions 11c′ and 11c″. In this case, a channel current Ich of the cell transistors flows along the bottom surfaces 11b and sidewalls 11s of the channel trench regions 11c′ and 11c″. The bottom surfaces 11b and the sidewalls 11s are {100} planes, as described above. Also, the direction of the channel current Ich that flows along the bottom surfaces 11b is parallel to the active region 13a (i.e., the x-axis), and a direction of the channel current Ich that flows along the sidewalls 11s is parallel to a z-axis perpendicular to the main surface 11t of the semiconductor substrate 11. The x- and z-axes are parallel to the <100> orientation as described with reference to FIG. 2B. Accordingly, the channel current Ich flows along the {100} planes in a direction parallel to the <100> orientation. As a result, according to the present embodiment, current drivability of the cell transistors may be improved. In particular, when the cell transistors are NMOS transistors, the current drivability of the cell transistors may be significantly improved.

Subsequently, a lower interlayer insulating layer 25 is formed on the semiconductor substrate 11 having the cell transistors. The lower interlayer insulating layer 25 may be formed of a silicon oxide layer.

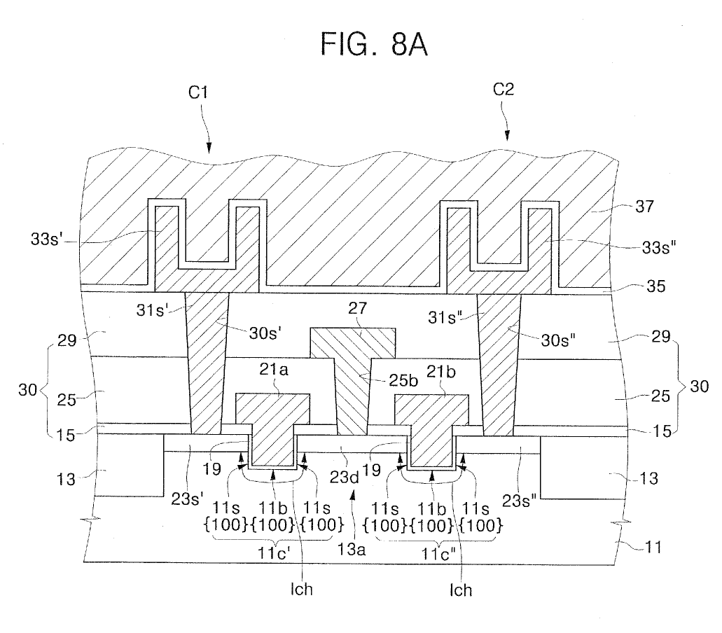

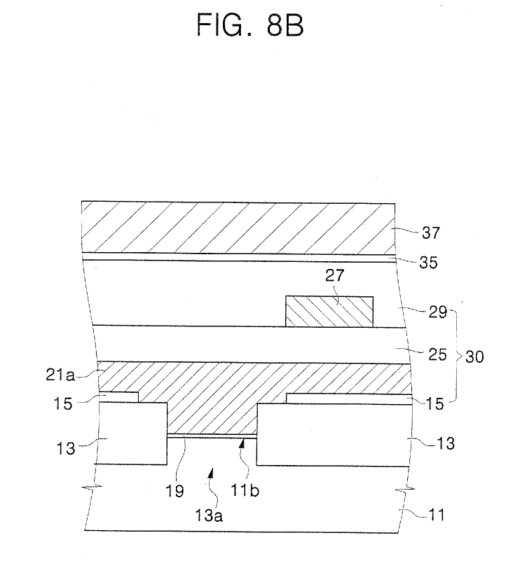

Referring to FIGS. 3, 8A, and 8B, the lower interlayer insulating layer 25 is patterned to form a bit line contact hole 25b exposing the common drain region 23d. A conductive layer is formed on the semiconductor substrate 11 having the bit line contact hole 25b, and the conductive layer is patterned to form a bit line 27 on the lower interlayer insulating layer 25. The bit line 27 is electrically connected to the common drain region 23d through the bit line contact hole 25b. Also, the bit line 27 may be formed to cross over the first and second gate electrodes 21a and 21b.

An upper interlayer insulating layer 29 is formed on the substrate having the bit line 27. The buffer oxide layer 15, the lower interlayer insulating layer 25, and the upper interlayer insulating layer 29 constitute an interlayer insulating layer 30. The interlayer insulating layer 30 is patterned to form a first storage node contact hole 30s′ and a second storage node contact hole 30s″ that expose the first and second source regions 23s′ and 23s″, respectively. A first storage node contact plug 31s′ and a second storage node contact plug 31s″ may be formed in the first and second storage node contact holes 30s′ and 30s″, respectively. The first and second storage node contact plugs 31s′ and 31s″ may be formed of a polysilicon layer.

A first storage node 33s′ and a second storage node 33s″ are formed on the first and second storage node contact plugs 31s′ and 31s″, respectively. The first and second storage nodes 33s′ and 33s″ may be formed using a conventional method. The first storage node 33s′ may be electrically connected to the first source region 23s′ through the first storage node contact plug 31s′, and the second storage node 33s″ may be electrically connected to the second source region 23s″ through the second storage node contact plug 31s″. A dielectric layer 35 and a plate electrode 37 are sequentially formed to cover the first and second storage nodes 33s′ and 33s″. The plate electrode 37, the dielectric layer 35, and the first storage node 33s′ constitute a first cell capacitor C1, and the plate electrode 37, the dielectric layer 35, and the second storage node 33s″ constitute a second cell capacitor C2.

The present invention is not limited to the above-described embodiments but may be modified in various different forms. For example, it may be apparent that the present invention can be applied to MOS transistors which employ the channel trench regions 1c in the first and second active regions 3a and 3b of FIG. 2A, as well as the channel trench region 11c′ in the second active region 13b of FIG. 2B as recessed channel regions.

Furthermore, the present invention can also be applicable to planar-type MOS transistors. In this case, the processes for forming the hard mask layer 18 and the channel trench regions 11c′ and 11c″, which are described with reference to FIGS. 4A, 4B, 5A, and 5B, may be omitted.

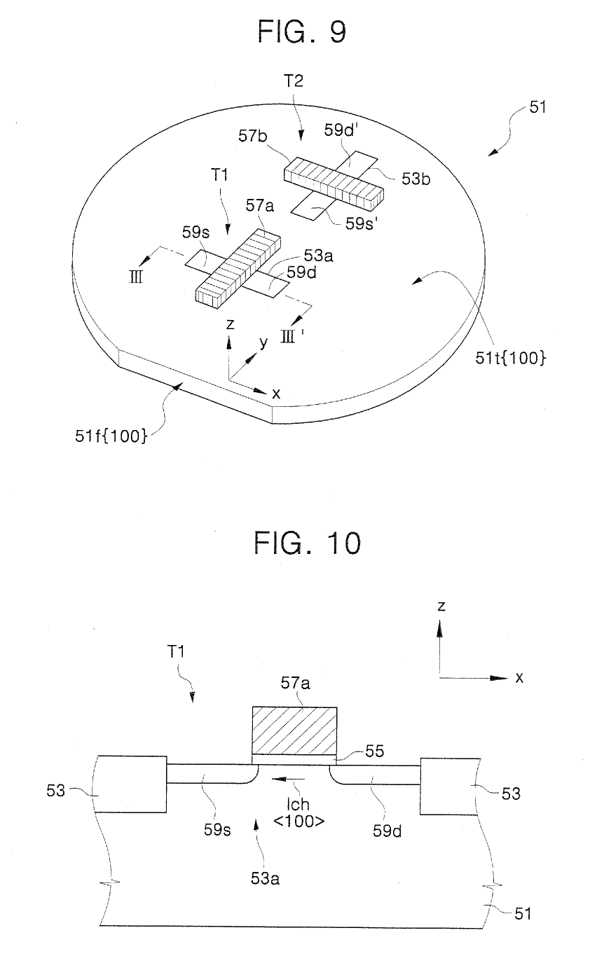

FIG. 9 is an isometric view of a semiconductor wafer having planar-type MOS transistors according to another embodiment of the present invention, and FIG. 10 is a cross-sectional view taken along line III-III′ of FIG. 9.

Referring to FIGS. 9 and 10, a semiconductor wafer 51 is provided. The semiconductor wafer 51 may be the same wafer as shown in FIG. 2B. That is, the semiconductor wafer 51 may include a main surface 51t of a (100) plane and a flat zone plane 51f of the (100) plane, and the semiconductor wafer 51 may be a single crystalline silicon wafer. Also, the main surface 51t is parallel to an x-y plane defined by an x-axis and a y-axis, and the flat zone plane 51f is parallel to an x-z plane defined by the x-axis and a z-axis. The x-, y-, and z-axes correspond to coordinate axes orthogonal to one another, and the x-axis is parallel to the flat zone plane 51f. As a result, all the x-, y-, and z-axes are coordinate axes parallel to a <100> orientation.

An isolation layer 53 is provided in a predetermined region of the main surface 51t to define a first active region 53a and a second active region 53b. Each of the first and second active regions 53a and 53b may have a width and a length greater than the width. In this case, the first active region 53a is disposed parallel to the x-axis, and the second active region 53b is disposed parallel to the y-axis. In other words, the first active region 53a is disposed parallel to the flat zone plane 51f, and the second active region 53b is disposed perpendicular to the flat zone plane 51f. As a result, the first and second active regions 53a and 53b are disposed parallel to the <100> orientation.

A first source region 59a and a first drain region 59d may be provided at opposing sides of the first active region 53a, respectively, and a first gate electrode 57a may be disposed to cross over a planar-type channel region composed of the first active region 53a between the first source and drain regions 59a and 59d. That is, the first gate electrode 57a may be disposed perpendicular to the flat zone plane 51f. Similarly, a second source region 59a′ and a second drain region 59d′ may be provided at opposing sides of the second active region 53b, respectively, and a second gate electrode 57b may be disposed to cross over a planar-type channel region composed of the second active region 53b between the second source region 59a′ and the second drain region 59d′. That is, the second gate electrode 57b may be disposed parallel to the flat zone plane 51f. The first and second gate electrodes 57a and 57b are electrically insulated from the planar-type channel regions by a gate insulating layer 55.

The first source region 59a, the first drain region 59d, and the first gate electrode 57a constitute a first planar-type MOS transistor T1, and the second source region 59a′, the second drain region 59d′, and the second gate electrode 57b constitute a second planar-type MOS transistor T2. In the first planar-type MOS transistor T1, a channel current Ich that flows from the first drain region 59d toward the first source region 59a may be parallel to the x-axis. That is, carriers that contribute to the channel current Ich of the first planar-type MOS transistor T1 move along the <100> orientation in the (100) plane. Accordingly, when the first planar-type MOS transistor T1 is an NMOS transistor, the current drivability of the first planar-type MOS transistor T1 may be significantly improved. Similarly, a channel current that flows from the second drain region 59d′ toward the second source region 59a′ may be parallel to the y-axis. That is, carriers that contribute to the channel current of the second planar-type MOS transistor T2 also move along the <100> orientation in the (100) plane. Accordingly, when the second planar-type MOS transistor T2 is an NMOS transistor, the current drivability of the second planar-type MOS transistor T2 may also be significantly improved.

Furthermore, planar-type MOS transistors according to other embodiments of the present invention may be provided on the semiconductor wafer 1 shown in FIG. 2A. That is, the planar-type MOS transistors according to the present invention may be formed on a semiconductor wafer having a main surface of a (100) plane and a flat zone plane of a (110) plane. In this case, active regions in which the planar-type MOS transistors are formed should be disposed to have an angle of 45° with respect to an x-axis parallel to the flat zone plane as shown in FIG. 2A. As a result, a channel current from drain regions of the planar-type MOS transistors toward source regions thereof flows along the <100> orientation.

### EXAMPLES

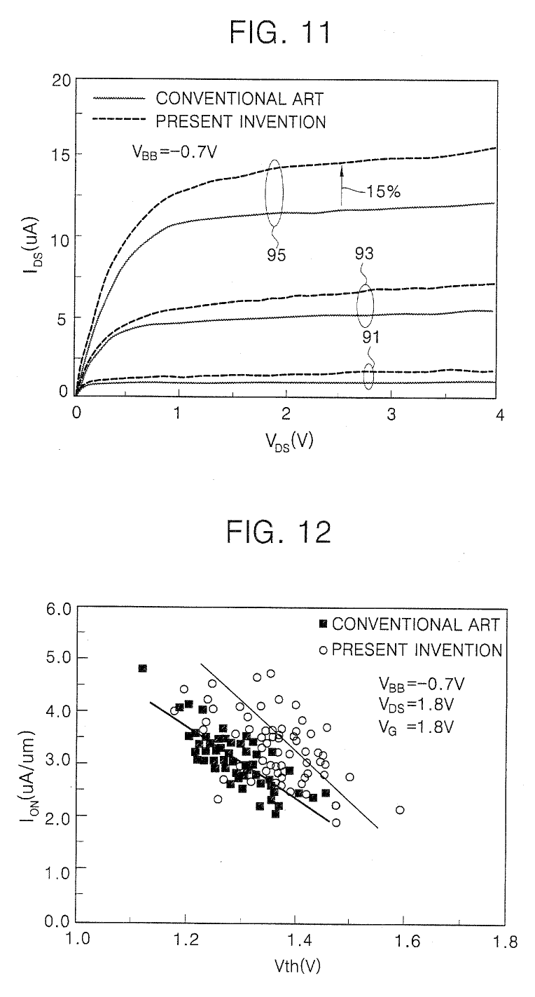

FIG. 11 is a graph showing drain current versus drain voltage characteristics of NMOS transistors fabricated according to the conventional art and the present invention. In FIG. 11, a horizontal axis indicates a drain voltage Vds, and a vertical axis indicates a drain current Ids. A reference numeral “91” indicates drain current measured at a gate voltage of 1.5 V, and a reference numeral “93” indicates drain current measured at a gate voltage of 2.0 V. Further, a reference numeral “95” indicates drain current measured at a gate voltage of 2.5 V. Moreover, all of the NMOS transistors were measured with a back gate bias V_{BB} of −0.7 V.

Each of the NMOS transistors exhibiting the measurement results of FIG. 11 was fabricated to have a channel trench region defining a recessed channel region. The recessed channel region was formed to a width of 0.088 micrometers (μm) (W of FIGS. 3 and 5B). Also, a bottom surface of the recessed channel region was formed to a width of 0.1 μm (WD of FIGS. 3 and 5A).

Further, conventional NMOS transistors were formed on a single crystalline silicon wafer having a main surface of a (100) plane and a flat zone plane of a (110) plane, and NMOS transistors according to the present invention were formed on a single crystalline silicon wafer having a main surface of a (100) plane and a flat zone plane of a (100) plane. In this case, all of the NMOS transistors exhibiting the measurement results of FIG. 11 were formed in active regions extending parallel to the flat zone planes. Thus, in the conventional NMOS transistors, bottom surfaces of the channel trench regions have {100} planes and sidewalls of the channel trench regions have {110} planes. Also, carriers (electrons) moving along the bottom surfaces are drifted in a <110> orientation, and carriers (electrons) moving along the sidewalls are drifted in a <100> orientation. On the contrary, in the NMOS transistors according to the present invention, all of bottom surfaces and sidewalls of the channel trench regions have {100} planes, and carriers (electrons) moving along the bottom surfaces and sidewalls all are drifted in a <100> orientation.

As can be seen from FIG. 11, drain currents of the NMOS transistors according to the present invention were increased by about 15% as compared to the conventional NMOS transistors.

FIG. 12 is a graph showing a relationship between on-currents and threshold voltages of the NMOS transistors exhibiting the measurement results of FIG. 11. In FIG. 12, a horizontal axis indicates a threshold voltage Vth, and a vertical axis indicates an on-current I_{ON}. The on-current I_{ON} corresponds to a drain current that flows from a drain region toward a source region when a ground voltage is applied to the source region and 1.8 V is applied to the drain region and a gate electrode.

As can be seen from FIG. 12, the on-currents I_{ON} of the NMOS transistors according to the present invention were increased as compared to the conventional NMOS transistors at the same threshold voltage level (the lighter straight line representing the average in accordance with the invention and the darker straight line representing the average in accordance with convention).

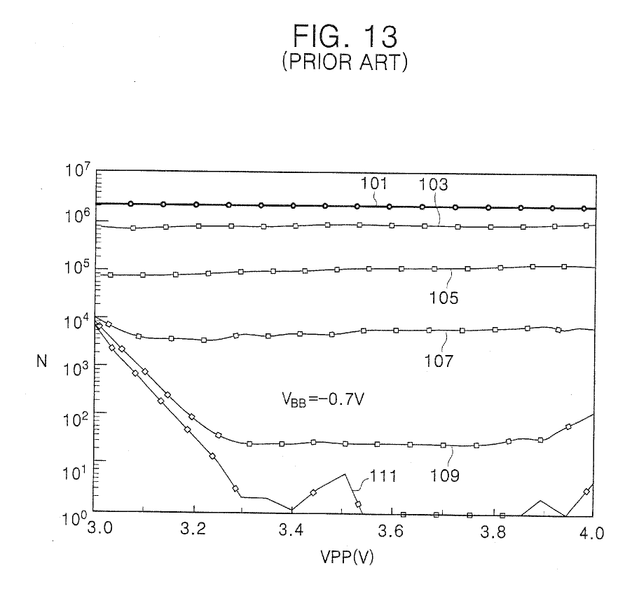

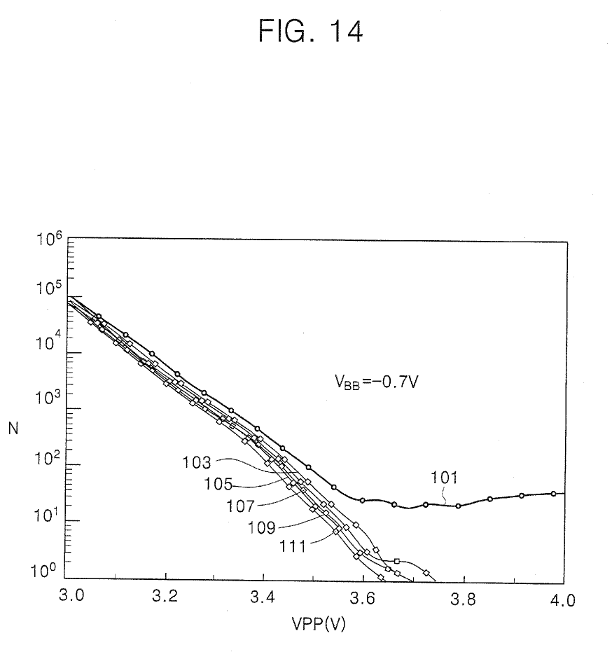

FIG. 13 is a graph showing a relationship between the number of failure bits N and word line voltages VPP of DRAM devices employing conventional MOS transistors as cell transistors, and FIG. 14 is a graph showing a relationship between the number of failure bits N and word line voltages VPP of DRAM devices employing MOS transistors according to an embodiment of the present invention as cell transistors. In FIGS. 13 and 14, reference numerals 101, 103, 105, 107, 109, and 111 indicate data measured after write operations are performed with word line pulse times tRDL of 5.0, 5.1, 5.2, 5.3, 5.4, and 5.5 nanoseconds (ns), respectively. The word line pulse time tRDL corresponds to a pulse width of the word line voltage signal which is applied to a word line during the write operation. Accordingly, when the word line pulse time tRDL and/or the word line voltage VPP are increased during the write operation, carriers and/or on current flowing through the cell transistors may be increased and the number of electric charges charged in cell capacitors connected to the cell transistors may be increased. In other words, when the word line pulse time tRDL and/or the word line voltage VPP are increased, the probability of write error may decrease to reduce the number of failure bits N. Nevertheless, the number of failure bits N of the conventional DRAM devices was not significantly reduced as shown in FIG. 13, even though the word line voltage VPP was increased. On the contrary, the number N of failure bits N of the DRAM devices according to the present invention was remarkably reduced as shown in FIG. 14, when the word line voltage VPP was increased. It can be understood that the foregoing measurement results are due to the current drivability of the cell transistors.

According to the present invention as described above, high performance MOS transistors may be designed such that carriers moving along a planar-type channel region or a recessed channel region are drifted along a <100> orientation in a (100) plane along both the bottom and the sidewalls defining the channel region. As a result, electrical characteristics of a semiconductor device employing the high performance MOS transistors can be improved.

Exemplary embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A MOS transistor comprising:
a semiconductor substrate having a main surface of a (100) plane;
an isolation layer provided in a predetermined region of the semiconductor substrate to define an active region;
a source region and a drain region provided in the active region, the source region and the drain region being disposed on a straight line parallel to a <100> orientation; and
an insulated gate electrode disposed over a channel region between the source and drain regions.

2. The MOS transistor according to claim 1, wherein the semiconductor substrate includes a flat zone plane perpendicular to the main surface, wherein the flat zone plane is a (100) plane.

3. The MOS transistor according to claim 2, wherein the source and drain regions are disposed on a straight line parallel to the flat zone plane.

4. The MOS transistor according to claim 3, wherein the gate electrode extends to cross over the active region and is perpendicular to the flat zone plane.

5. The MOS transistor according to claim 3, wherein the channel region is a planar-type channel region.

6. The MOS transistor according to claim 3, wherein the channel region is a recessed channel region that is defined by a cell trench region having a bottom surface lower than the source and drain regions as well as first and second sidewalls facing each other,
wherein the first and second sidewalls are adjacent to the source and drain regions, respectively, the bottom surface is a (100) plane parallel to the main surface, and the first and second sidewalls are {100} planes perpendicular to the flat zone plane.

7. The MOS transistor according to claim 2, wherein the source and drain regions are disposed on a straight line perpendicular to the flat zone plane.

8. The MOS transistor according to claim 7, wherein the gate electrode extends to cross over the active region and is parallel to the flat zone plane.

9. The MOS transistor according to claim 7, wherein the channel region is a planar-type channel region.

10. The MOS transistor according to claim 7, wherein the channel region is a recessed channel region that is defined by a cell trench region having a bottom surface lower than the source and drain regions as well as first and second sidewalls facing each other,
wherein the first and second sidewalls are adjacent to the source and drain regions, respectively, the bottom surface is a (100) plane parallel to the main surface, and the first and second sidewalls are {100} planes parallel to the flat zone plane.

11. The MOS transistor according to claim 1, wherein the semiconductor substrate includes a flat zone plane perpendicular to the main surface, and the flat zone plane is a (110) plane.

12. The MOS transistor according to claim 11, wherein the source and drain regions are disposed on a straight line that intersects the flat zone plane at an angle of about 45°.

13. The MOS transistor according to claim 12, wherein the gate electrode is substantially orthogonal to the active region.

14. The MOS transistor according to claim 12, wherein the channel region is a planar-type channel region.

15. The MOS transistor according to claim 12, wherein the channel region is a recessed channel region that is defined by a cell trench region having a bottom surface lower than the source and drain regions as well as first and second sidewalls facing each other,
wherein the first and second sidewalls are adjacent to the source and drain regions, respectively, the bottom surface is a (100) plane parallel to the main surface, and the first and second sidewalls are {100} planes that intersect the flat zone plane at an angle of about 45°.

16. The MOS transistor according to claim 1, wherein the channel region is a planar-type channel region.

17. The MOS transistor according to claim 1, wherein the channel region is a recessed channel region that is defined by a cell trench region having a bottom surface lower than the source and drain regions as well as first and second sidewalls facing each other,
wherein the first and second sidewalls are adjacent to the source and drain regions, respectively, and the bottom surface and the first and second sidewalls are {100} planes.

18. A semiconductor device comprising:
a semiconductor substrate having a main surface of a (100) plane;
an isolation layer provided in a predetermined region of the semiconductor substrate to define an active region;
a source region and a drain region provided in the active region, the source and drain regions being disposed on a straight line parallel to a <100> orientation;
an insulated word line disposed over a channel region between the source and drain regions, the insulated word line extending to cross over the active region;
a first interlayer insulating layer covering the word line, the source region and the drain region;
a bit line disposed on the first interlayer insulating layer and electrically connected to the drain region;
a second interlayer insulating layer covering the bit line and the first interlayer insulating layer;
a storage node electrode disposed on the second interlayer insulating layer and electrically connected to the source region;
a dielectric layer covering the storage node electrode; and
a plate electrode covering the dielectric layer.

19. The semiconductor device according to claim 18, wherein the semiconductor substrate includes a flat zone plane perpendicular to the main surface, wherein the flat zone plane is a (100) plane.

20. The semiconductor device according to claim 19, wherein the source and drain regions are disposed on a straight line parallel to the flat zone plane.

21. The semiconductor device according to claim 20, wherein the word line is disposed perpendicular to the flat zone plane.

22. The semiconductor device according to claim 20, wherein the channel region is a planar-type channel region.

23. The semiconductor device according to claim 20, wherein the channel region is a recessed channel region that is defined by a cell trench region having a bottom surface lower than the source and drain regions as well as first and second sidewalls facing each other,
wherein the first and second sidewalls are adjacent to the source and drain regions, respectively, the bottom surface is a (100) plane parallel to the main surface, and the first and second sidewalls are {100} planes perpendicular to the flat zone plane.

24. The semiconductor device according to claim 19, wherein the source and drain regions are disposed on a straight line perpendicular to the flat zone plane.

25. The semiconductor device according to claim 24, wherein the word line is parallel to the flat zone plane.

26. The semiconductor device according to claim 24, wherein the channel region is a planar-type channel region.

27. The semiconductor device according to claim 24, wherein the channel region is a recessed channel region that is defined by a cell trench region having a bottom surface lower than the source and drain regions as well as first and second sidewalls facing each other,
wherein the first and second sidewalls are adjacent to the source and drain regions, respectively, the bottom surface is a (100) plane parallel to the main surface, and the first and second sidewalls are {100}) planes parallel to the flat zone plane.

28. The semiconductor device according to claim 18, wherein the semiconductor substrate includes a flat zone plane perpendicular to the main surface, and the flat zone plane is a (110) plane.

29. The semiconductor device according to claim 28, wherein the source and drain regions are disposed on a straight line that intersects the flat zone plane at an angle of about 45°.

30. The semiconductor device according to claim 29, wherein the word line is substantially orthogonal to the active region.

31. The semiconductor device according to claim 29, wherein the channel region is a planar-type channel region.

32. The semiconductor device according to claim 29, wherein the channel region is a recessed channel region that is defined by a cell trench region having a bottom surface lower than the source and drain regions as well as first and second sidewalls facing each other,
wherein the first and second sidewalls are adjacent to the source and drain regions, respectively, the bottom surface is a (100) plane parallel to the main surface, and the first and second sidewalls are {100} planes that intersect the flat zone plane at an angle of about 45°.

33. The semiconductor device according to claim 18, wherein the channel region is a planar-type channel region.

34. The semiconductor device according to claim 18, wherein the channel region is a recessed channel region that is defined by a cell trench region having a bottom surface lower than the source and drain regions as well as first and second sidewalls facing each other,
wherein the first and second sidewalls are adjacent to the source and drain regions, respectively, and the bottom surface and the first and second sidewalls are {100} planes.

35. A method of fabricating a semiconductor device, comprising:
providing a semiconductor substrate having a main surface of a (100) plane;
forming an isolation layer in a predetermined region of the semiconductor substrate to define an active region, the active region being defined to have a length direction parallel to a <100> orientation;
forming an insulated gate electrode crossing over the active region; and
implanting impurity ions into the active region using the gate electrode as an ion implantation mask to form a source region and a drain region.

36. The method according to claim 35, wherein the semiconductor substrate includes a flat zone plane perpendicular to the main surface, and the flat zone plane is a (100) plane.

37. The method according to claim 36, wherein the active region is formed parallel to the flat zone plane.

38. The method according to claim 37, further comprising etching a portion of the active region to form a cell trench region that crosses the active region prior to formation of the insulated gate electrode,
wherein the cell trench region is formed to have an inner wall which includes a bottom surface lower than a surface of the active region as well as first and second sidewalls facing each other, the bottom surface and the first and second sidewalls are formed to have a (100) plane orientation, and the gate electrode is formed to cover the inner wall of the cell trench region.

39. The method according to claim 38, wherein the source and drain regions are formed to have a junction depth shallower than the cell trench region.

40. The method according to claim 36, wherein the active region is formed so that the length direction of the active region is perpendicular to the flat zone plane.

41. The method according to claim 40, further comprising etching a portion of the active region to form a cell trench region that crosses the active region prior to formation of the insulated gate electrode,
wherein the cell trench region is formed to have an inner wall which includes a bottom surface lower than a surface of the active region as well as first and second sidewalls facing each other, the bottom surface and the first and second sidewalls are formed to have a (100) plane orientation, and the gate electrode is formed to cover the inner wall of the cell trench region.

42. The method according to claim 41, wherein the source and drain regions are formed to have a junction depth shallower than the cell trench region.

43. The method according to claim 35, wherein the semiconductor substrate includes a flat zone plane perpendicular to the main surface, and the flat zone plane is a (110) plane.

44. The method according to claim 43, wherein the active region is formed parallel to a straight line that intersects the flat zone plane at an angle of about 45°.

45. The method according to claim 44, further comprising etching a portion of the active region to form a cell trench region that crosses the active region prior to formation of the insulated gate electrode,
wherein the cell trench region is formed to have an inner wall which includes a bottom surface lower than a surface of the active region as well as first and second sidewalls facing each other, the bottom surface and the first and second sidewalls are formed to have a (100) plane orientation, and the gate electrode is formed to cover the inner wall of the cell trench region.

46. The method according to claim 45, wherein the source and drain regions are formed to have a junction depth shallower than the cell trench region.

47. The method according to claim 35, further comprising etching a portion of the active region to form a cell trench region that crosses the active region prior to formation of the insulated gate electrode,
wherein the cell trench region is formed to have an inner wall which includes a bottom surface lower than a surface of the active region as well as first and second sidewalls facing each other, the bottom surface and the first and second sidewalls are formed to have a (100) plane orientation, and the gate electrode is formed to cover the inner wall of the cell trench region.

48. The method according to claim 47, wherein the source and drain regions are formed to have a junction depth shallower than the cell trench region.

49. The method according to claim 35, further comprising:
forming a first interlayer insulating layer on the gate electrode and the source and drain regions;
forming a bit line electrically connected to the drain region on the first interlayer insulating layer;
forming a second interlayer insulating layer on the bit line and the first interlayer insulating layer;
forming a storage node electrode electrically connected to the source region on the second interlayer insulating layer;
forming a dielectric layer on the storage node electrode; and
forming a plate electrode on the dielectric layer.
